(19) United States
(12) Patent Application Publication
(10) Pub. No.: US 2013/0221375 A1
(43) Pub. Date: Aug. 29, 2013

(54) SILICON CARBIDE SEMICONDUCTOR DEVICE AND METHOD FOR MANUFACTURING SAME

(71) Applicant: Sumitomo Electric Industries, Ltd., (US)

(72) Inventor: Hiromu SHIOMI, Osaka-shi (JP)

(73) Assignee: SUMITOMO ELECTRIC INDUSTRIES, LTD., Osaka-shi (JP)

(21) Appl. No.: 13/748,012

(22) Filed: Jan. 23, 2013

Related U.S. Application Data
(60) Provisional application No. 61/602,411, filed on Feb. 23, 2012.

(30) Foreign Application Priority Data
Feb. 23, 2012 (JP) 2012-036911

(51) Int. Cl. H01L 29/66; H01L 29/78

(52) U.S. Cl. CPC H01L 29/66068; H01L 29/7802
USPC 257/77; 438/268

(57) ABSTRACT

A silicon carbide semiconductor device includes an epitaxial layer, a gate insulating film, a gate electrode, a drain electrode, and a source electrode. The epitaxial layer is made of silicon carbide includes a mesa structure region having a top surface forming a first main surface and a side surface. The gate insulating film is provided on the top surface of the mesa structure region. The gate electrode is provided on the gate insulating film. The mesa structure region includes a first impurity region, a second impurity region, and a third impurity region. The source electrode is in contact with the third impurity region. In this way, there can be provided a silicon carbide semiconductor device having breakdown voltage improved by reducing electric field strength in the gate insulating film, as well as a method for manufacturing such a silicon carbide semiconductor device.

### BACKGROUND OF THE INVENTION

1. Field of the Invention

The present invention relates to a silicon carbide semiconductor device and a method for manufacturing the silicon carbide semiconductor device, more particularly, a silicon carbide semiconductor device having a mesa structure region and a method for manufacturing such a silicon carbide semiconductor device.

2. Description of the Background Art

In recent years, there has been examined a method for manufacturing a MOSFET (Metal Oxide Semiconductor Field Effect Transistor) using silicon carbide. The MOSFET has a well region formed by, for example, implanting impurity ions into a silicon carbide layer. According to a method disclosed in Japanese Patent Laying-Open No. 6-151860, ion implantation into a silicon carbide substrate is performed using, as a mask, a gate electrode having an inclined surface, thereby forming a p region (well region). Meanwhile, according to a method disclosed in Japanese Patent Laying-Open No. 2004-39744, a base region (well region) is formed by forming a mask having an inclined surface on an epitaxial film and thereafter implanting impurity ions into the epitaxial film from above the mask.

In the MOSFET described in each of Japanese Patent Laying-Open No. 6-151860 and Japanese Patent Laying-Open No. 2004-39744, the breakdown voltage of the device is substantially determined by breakdown voltage of the gate insulating film. In the MOSFET having such a structure, electric field strength becomes high in the gate insulating film. This makes it difficult to improve the breakdown voltage of the device.

### SUMMARY OF THE INVENTION

The present invention has been made to solve the foregoing problem, and has its object to provide a silicon carbide semiconductor device having breakdown voltage improved by reducing electric field strength in a gate insulating film, as well as a method for manufacturing such a silicon carbide semiconductor device.

A silicon carbide semiconductor device according to the present invention includes an epitaxial layer, a gate insulating film, a gate electrode, a drain electrode, and a source electrode. The epitaxial layer is made of silicon carbide, has a first main surface and a second main surface opposite to the first main surface, and includes a mesa structure region having a top surface forming the first main surface and a side surface. The gate insulating film is provided on the top surface of the mesa structure region. The gate electrode is provided on the gate insulating film. The mesa structure region includes a first impurity region having first conductivity type and an impurity implantation region provided in the side surface. The impurity implantation region includes a second impurity region and a third impurity region. The second impurity region has second conductivity type different from the first conductivity type, and is in contact with the gate insulating film. The third impurity region covers the second impurity region in the side surface, is separated from the first impurity region by the second impurity region, and has the first conductivity type. The drain electrode is provided on the second main surface. The source electrode is in contact with the third impurity region.

According to the silicon carbide semiconductor device in the present invention, the gate insulating film is formed on the top surface of the mesa structure region. This leads to reduced electric field strength in the gate insulating film, thereby improving breakdown voltage. The following describes a reason why the electric field strength in the gate insulating film can be reduced.

Referring to FIG. 15, the following description is directed to a schematic view (FIG. 15(a)) of electric lines of force 51-55 in a silicon carbide semiconductor device having the mesa structure region, and a schematic view (FIG. 15(b)) of electric lines of force 51-55 of a silicon carbide semiconductor device having no mesa structure region. As shown in FIG. 15(b), the electric lines of force are very crowded around the gate insulating film in the silicon carbide semiconductor device having no mesa structure region. On the other hand, as shown in FIG. 15(a), in the silicon carbide semiconductor device having the mesa structure region, the electric lines of force are sparse around the gate insulating film as compared with those in the silicon carbide semiconductor device having no mesa structure region. It is meant that electric field strength is large in a portion in which electric lines of force 51-55 are crowded, whereas electric field strength is small in a portion in which electric lines of force 51-55 are sparse. Specifically, the electric field strength around the gate insulating film of the silicon carbide semiconductor device having the mesa structure region is smaller than the electric field strength around the gate insulating film of the silicon carbide semiconductor device having no mesa structure region. Accordingly, breakdown voltage of the silicon carbide semiconductor device having the mesa structure region becomes higher than that of the silicon carbide semiconductor device having no mesa structure region.

Preferably in the silicon carbide semiconductor device, the third impurity region is in contact with the gate insulating film.

Preferably in the silicon carbide semiconductor device, the side surface is inclined relative to a {0001} plane. With the side surface thus inclined relative to the {0001} plane, propagation of crystal periodicity is likely to be attained when annealing the impurity regions. Accordingly, the annealing temperature can be reduced.

Preferably in the silicon carbide semiconductor device, the side surface and a bottom surface of the mesa structure region form an angle of not less than 45° and not more than 100°. When the angle is not less than 45°, the breakdown voltage of the silicon carbide semiconductor device can be improved without making the size of the bottom surface of the mesa structure region too large. Meanwhile, when the angle is not more than 100°, electric field concentration can be suppressed at the intersection portion between the upper surface and the side surface. Accordingly, high breakdown voltage of the silicon carbide semiconductor device can be maintained.

A method for manufacturing a silicon carbide semiconductor device in the present invention is a method for manufacturing a silicon carbide semiconductor device that includes a mesa structure region having a top surface and a side surface and that is provided with a gate electrode on the top surface with a gate insulating film interposed therebetween. The method includes the following steps. There is formed an epitaxial layer that is made of silicon carbide, that has a first main surface and a second main surface opposite to the first main surface, and that has a first impurity region having first conductivity type. There is formed a first mask on the first main surface of the epitaxial layer. There is formed the mesa structure region in the first main surface of the epitaxial layer by etching the first main surface of the epitaxial layer using the first mask. There is formed an impurity implantation region in the side surface of the mesa structure region. The step of following the impurity implantation region includes the step of forming a second impurity region having second conductivity type different from the first conductivity type and a third impurity region having the first conductivity type. The second impurity region is formed in contact with the gate insulating film. The third impurity region is formed to cover the second impurity region in the side surface and to be separated from the first impurity region by the second impurity region. There is formed a drain electrode on the second main surface of the epitaxial layer. There is formed a source electrode in contact with the third impurity region.

According to the method for manufacturing the silicon carbide semiconductor device in the present invention, there can be manufactured a silicon carbide semiconductor device having a mesa structure region having a top surface on which a gate insulating film is formed. Accordingly, there can be obtained a silicon carbide semiconductor device having improved breakdown voltage.

Preferably in the method for manufacturing the silicon carbide semiconductor device, the first mask includes the gate insulating film and the gate electrode formed on the gate insulating film. In this way, each of the gate insulating film and the gate electrode is employed as a mask, thus simplifying the manufacturing process.

Preferably in the method for manufacturing the silicon carbide semiconductor device, the step of forming the impurity implantation region includes the step of performing ion implantation of an impurity having the first conductivity type and an impurity having the second conductivity type in a direction inclined relative to a surface of the first mask. In this way, the ions are implanted into the side surface of the mesa structure region.

Preferably, the method for manufacturing the silicon carbide semiconductor device further includes the step of annealing the mesa structure region at a temperature lower than 1700° C. after the step of forming the impurity implantation region. In this way, the annealing temperature can be reduced, thus suppressing surface roughness.

Preferably in the method for manufacturing the silicon carbide semiconductor device, the step of forming the impurity implantation region includes the following steps. There is performed ion implantation of an impurity having the second conductivity type into the side surface. There is formed a second mask to cover a portion of a region provided with the impurity having the second conductivity type by means of the ion implantation. There is performed ion implantation of an impurity having the first conductivity type into the region provided with the impurity having the second conductivity type by means of the ion implantation, using the second mask.

Preferably in the method for manufacturing the silicon carbide semiconductor device, the step of forming the impurity implantation region includes the following steps. There is performed ion implantation of an impurity having the second conductivity type into the side surface. There is performed ion implantation of an impurity having the first conductivity type into a region provided with the impurity having the second conductivity type by means of the ion implantation. There is formed a second mask to cover a portion of a region provided with the impurity having the first conductivity type by means of the ion implantation. There is performed ion implantation of an impurity having the second conductivity type into the region provided with the impurity having the first conductivity type by means of the ion implantation, using the second mask.

Preferably in the method for manufacturing the silicon carbide semiconductor device, the step of forming the impurity implantation region includes the following steps. There is performed ion implantation of an impurity having the second conductivity type into the side surface. The first main surface of the epitaxial layer is inclined relative to a direction in which the ion implantation is performed. While keeping the inclination relative to the direction in which the ion implantation is performed, there is performed ion implantation of an impurity having the first conductivity type into a region provided with the impurity having the second conductivity type by means of the ion implantation. In this way, only one mask is used in forming the impurity regions, thus simplifying the manufacturing process.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view schematically showing a silicon carbide semiconductor device in one embodiment of the present invention.

FIG. 2 is a schematic cross sectional view schematically showing a first step of a method for manufacturing the silicon carbide semiconductor device in the embodiment of the present invention.

FIG. 3 is a schematic cross sectional view schematically showing a second step of the method for manufacturing the silicon carbide semiconductor device in the embodiment of the present invention.

FIG. 4 is a schematic cross sectional view schematically showing a third step of the method for manufacturing the silicon carbide semiconductor device in the embodiment of the present invention.

FIG. 5 is a schematic cross sectional view schematically showing a fourth step of the method for manufacturing the silicon carbide semiconductor device in the embodiment of the present invention.

FIG. 6 is a schematic cross sectional view schematically showing a fifth step of the method for manufacturing the silicon carbide semiconductor device in the embodiment of the present invention.

FIG. 7 is a schematic cross sectional view schematically showing a sixth step of the method for manufacturing the silicon carbide semiconductor device in the embodiment of the present invention.

FIG. 8 is a schematic cross sectional view schematically showing a seventh step of the method for manufacturing the silicon carbide semiconductor device in the embodiment of the present invention.

FIG. 9 is a schematic cross sectional view schematically showing an eighth step of the method for manufacturing the silicon carbide semiconductor device in the embodiment of the present invention.

FIG. 10 is a schematic cross sectional view schematically showing a first variation of the fifth to seventh steps in the method for manufacturing the silicon carbide semiconductor device in the embodiment of the present invention.

FIG. 11 is a schematic cross sectional view schematically showing the first variation of the fifth to seventh steps in the method for manufacturing the silicon carbide semiconductor device in the embodiment of the present invention.

FIG. 12 is a schematic cross sectional view schematically showing the first variation of the fifth to seventh steps in the method for manufacturing the silicon carbide semiconductor device in the embodiment of the present invention.

FIG. 13 is a schematic cross sectional view schematically showing a second variation of the fifth to seventh steps in the method for manufacturing the silicon carbide semiconductor device in the embodiment of the present invention.

FIG. 14 is a flowchart schematically showing the method for manufacturing the silicon carbide semiconductor device in the embodiment of the present invention.

FIG. 15A is a schematic view showing electric lines of force in a silicon carbide semiconductor device having a mesa structure region.

FIG. 15B is a schematic view showing electric lines of force in a silicon carbide semiconductor device having no mesa structure region.

### DESCRIPTION OF THE PREFERRED EMBODIMENTS

The following describes an embodiment of the present invention based on figures. It should be noted that in the below-mentioned figures, the same or corresponding portions are given the same reference characters and are not described repeatedly.

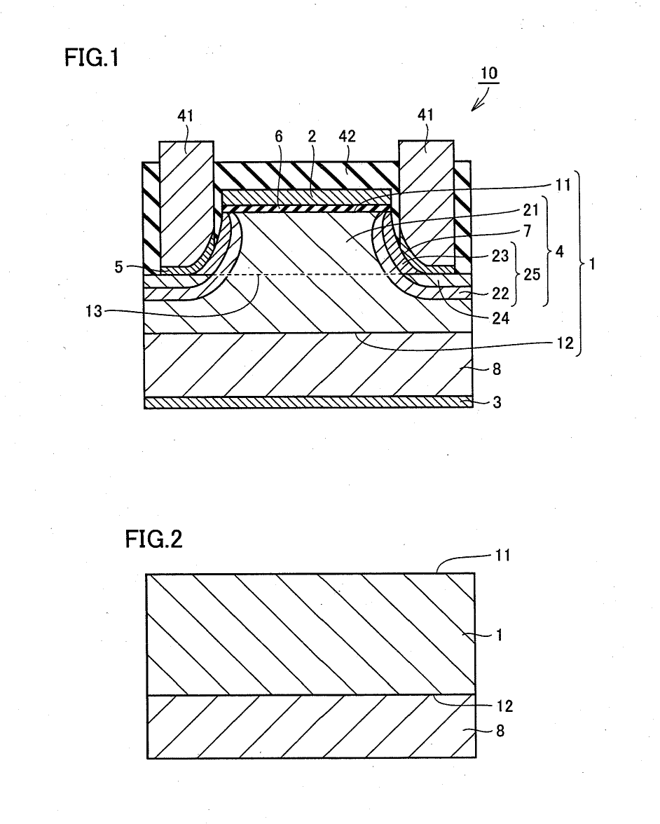

Referring to FIG. 1, a silicon carbide semiconductor device 10 of the present embodiment is a vertical type DiMOSFET (Double Implanted Metal Oxide Semiconductor Field Effect Transistor), and mainly includes an epitaxial layer 1, a drain electrode 3, a mesa structure region 4, a gate electrode 2, and source electrodes 5. Epitaxial layer 1 is made of silicon carbide, and has a first main surface 11 and a second main surface 12 opposite to first main surface 11. Epitaxial layer 1 includes a mesa structure region 4 having a top surface 11 (constituting a portion of first main surface 11) and side surfaces 7.

Mesa structure region 4 has a first impurity region 21, second impurity regions 22, and third impurity regions 23. Mesa structure region 4 is trapezoidal when viewed in a direction perpendicular to a plane of sheet, for example. In the present embodiment, first impurity region 21 is an n region (region having first conductivity type). Each of second impurity regions 22 is a p region (region having second conductivity type). Each of third impurity regions 23 is an n region (region having the first conductivity type). These three impurity regions form an npn junction. An impurity implantation region 25 is provided in each of side surfaces 7 of mesa structure region 4.

Further, impurity implantation region 25 includes: the p region that is second impurity region 22; and the n region that is third impurity region 23. The second impurity region is an impurity region of p type (second conductivity type), and makes contact with a gate insulating film 6 at top surface 11 of mesa structure region 4. Third impurity region 23 is an impurity region of n type (first conductivity type), and covers second impurity region 22 in side surface 7 of mesa structure region 4. Further, third impurity region 23 is separated from first impurity region 21 by second impurity region 22. It should be noted that in the present embodiment, third impurity region 23 is in contact with gate insulating film 6.

In the present embodiment, epitaxial layer 1 includes p+ regions, each of which serves as a fourth impurity region 24. The p+ region is provided in contact with bottom surface 13 of mesa structure region 4. The p+ region is in contact with source electrode 5.

Gate insulating film 6 is provided on top surface 11 of mesa structure region 4. Gate electrode 2 is provided on gate insulating film 6. On gate electrode 2, an interlayer insulating film 42 is provided.

Source electrode 5 is in contact with third impurity region 23. On source electrode 5, a wire 41 is foamed to extend in a direction perpendicular to substrate 8. In the present embodiment, source electrode 5 is in contact with side surface 7 of mesa structure region 4 and the p+ region.

Drain electrode 3 is provided on second main surface 12 of epitaxial layer 1. Here, the expression “drain electrode 3 is provided on second main surface 12 of epitaxial layer 1” is intended to also include a case where drain electrode 3 is provided on second main surface 12 of epitaxial layer 1 with substrate 8 being interposed therebetween. In the present embodiment, drain electrode 3 is formed on substrate 8.

Substrate 8 is made of silicon carbide having n type conductivity, for example. Epitaxial layer 1 is formed on substrate 8. Epitaxial layer 1 is made of silicon carbide having n type conductivity, for example. Epitaxial layer 1 contains an n type conductive impurity at a concentration of, for example, 5×10¹⁵ cm⁻³.

Preferably, side surface 7 of mesa structure region 4 is inclined relative to a {0001} plane (i.e., a basal plane). Side surface 7 of mesa structure region 4 is inclined by, for example, 10° or greater relative to the {0001} plane.

In the present embodiment, mesa structure region 4 has a width (size in a direction parallel to first main surface 11) getting larger from first main surface 11 toward second main surface 12 when laterally viewed. Side surface 7 and bottom surface 13 of mesa structure region 4 form an angle of 80°, for example. Further, the size of top surface 11 of mesa structure region 4 may be smaller than the size of bottom surface 13 thereof. Alternatively, the size of top surface 11 may be the same as the size of bottom surface 13. Preferably, side surface 7 and bottom surface 13 of mesa structure region 4 may form an angle of not less than 45° and not more than 100°.

It should be noted that in the description of the present embodiment, n type is assumed to be the first conductivity type and p type is assumed to be the second conductivity type, but the present invention is not limited to this. For example, p type may be the first conductivity type and n type may be the second conductivity type.

The following describes a method for manufacturing silicon carbide semiconductor device 10 in the present embodiment. The method for manufacturing silicon carbide semiconductor device 10 in the present embodiment is a method for manufacturing a silicon carbide semiconductor device including mesa structure region 4 having top surface 11 and side surface 7, wherein gate electrode 2 is provided on top surface 11 with gate insulating film 6 interposed therebetween. The method mainly includes the following steps.

Referring to FIG. 2, first, in a substrate preparing step (step S10: FIG. 14), substrate 8 made of silicon carbide is prepared. Substrate 8 has, for example, n type (first conductivity type) conductivity. Substrate 8 has a diameter of 100 mmφ. Substrate 8 has a polytype of 4H. Substrate 8 has a main surface corresponding to the {0001} plane. This substrate 8 is fabricated by slicing an ingot grown by means of a Modified-Lely method and thereafter performing mirror polishing thereto, for example. Substrate 8 has a resistivity of, for example, 0.017 Ωcm. Substrate 8 has a thickness of, for example, 400 μm.

Next, an epitaxial layer forming step (step S20: FIG. 14) is performed to form epitaxial layer 1 in the following manner. First, a thermal CVD (Chemical Vapor Deposition) method is employed to epitaxially grow epitaxial layer 1 on the surface of substrate 8. The temperature of the substrate is set at, for example, 1550° C. As a source material gas, silane or propane is used, for example. For example, a dopant gas is nitrogen, a carrier gas is hydrogen, and a pressure is 100 mbar.

Epitaxial layer 1 contains an n type impurity at a concentration of, for example, 9×10¹⁵ cm⁻². The fluctuation of concentration, which is a ratio obtained by dividing (the maximum concentration−the minimum concentration) by the average concentration, is less than 5%. Further, epitaxial layer 1 has a thickness of, for example, 12 μm. The fluctuation of thickness, which is a ratio obtained by dividing (the maximum thickness−the minimum thickness) by the average thickness, is less than 3%.

Epitaxial layer 1 has first main surface 11, and second main surface 12 opposite to first main surface 11.

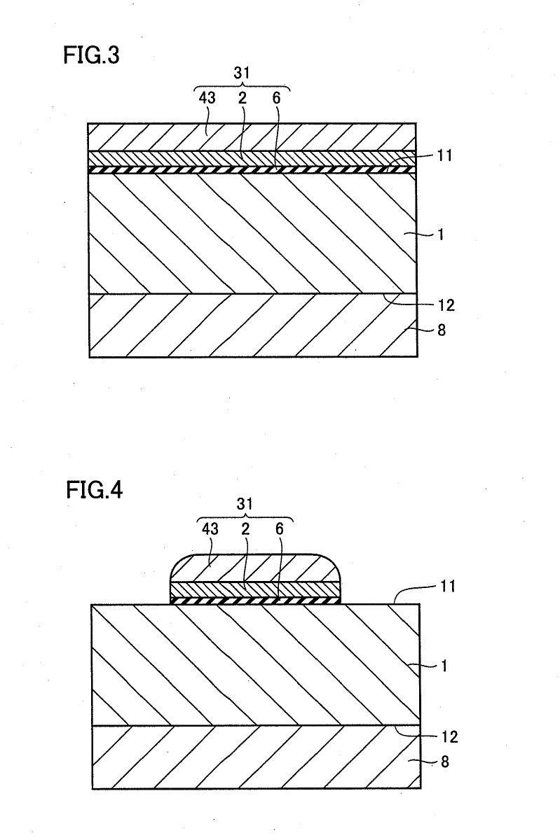

Referring to FIG. 3, a thermal oxidation film 6 is formed at first main surface 11 of epitaxial layer 1, so as to have a film thickness of, for example, 50 nm. Thermal oxidation film 6 is formed by thermally oxidizing epitaxial layer 1 at 1250° C. Thereafter, NO annealing treatment is performed in a nitrogen monoxide (NO) atmosphere, for example. Thereafter, for example, in an argon (Ar) atmosphere, Ar annealing treatment is performed at 1300° C. Thermal oxidation film 6 will serve as gate insulating film 6 in the device. Thereafter, a low-resistance polysilicon 2 doped with phosphorus is foamed on thermal oxidation film 6 using the thermal CVD method. Low-resistance polysilicon 2 has a film thickness of, for example, 600 nm. Low-resistance polysilicon 2 will serve as gate electrode 2 in the device. On low-resistance polysilicon 2, a TEOS (Tetra Ethyl Ortho Silicate) oxide film 43 is formed. TEOS oxide film 43 has a film thickness of, for example, 1.8 μm.

Referring to FIG. 4, in a mask forming step (step S30: FIG. 14), a mask (first mask 31) is formed. Specifically, TEOS oxide film 43 is etched using CHF₃ and O₂ with parallel plate type RF (Radio Frequency) etching, thereby forming first mask 31. In this way, first mask 31 thus formed of gate insulating film 6, gate electrode 2, and TEOS oxide film 43 is formed on first main surface 11 of epitaxial layer 1.

Referring to FIG. 5, a mesa structure region forming step (step S40: FIG. 14) is performed. Specifically, epitaxial layer 1 made of silicon carbide is etched by, for example, 1.5 μm using first mask 31. The etching is performed using SF₆ and O₂ gas, by an ECR (Electron Cyclotron Resonance) plasma etcher. By etching first main surface 11 of epitaxial layer 1 using first mask 31 in this way, epitaxial layer 1 is formed into a shape including mesa structure region 4 having top surface 11 and side surfaces 7.

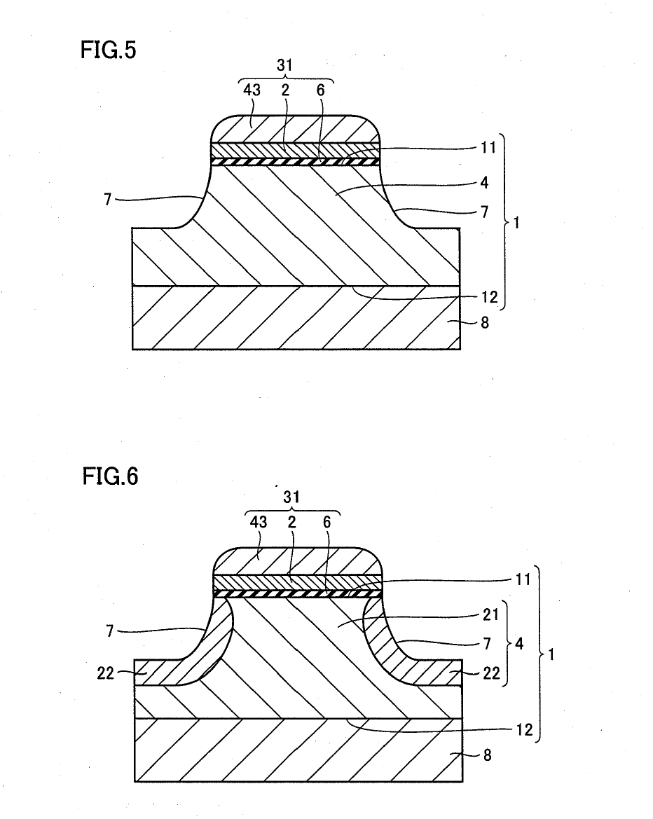

Referring to FIG. 6, an ion implantation step (step S50: FIG. 14) is performed. In the ion implantation step, impurity implantation region 25 is formed in each of side surfaces 7 of mesa structure region 4. Formed in the step of forming impurity implantation region 25 are second impurity region 22 having the second conductivity type and third impurity region 23 having the first conductivity type. Specifically, ion implantation of Al (aluminum) is obliquely performed into epitaxial layer 1, thereby forming second impurity region 22 having p type conductivity (second conductivity type). The ion implantation is performed in a direction inclined relative to a normal direction of first main surface 11. More specifically, the ion implantation is performed into side surface 7 of mesa structure region 4. The ion implantation is performed in such a manner that, for example, divalent ions of Al are implanted under a condition of 300 keV at a dose amount of 5×10¹⁴cm⁻². It should be noted that second impurity region 22 is formed in contact with gate insulating film 6.

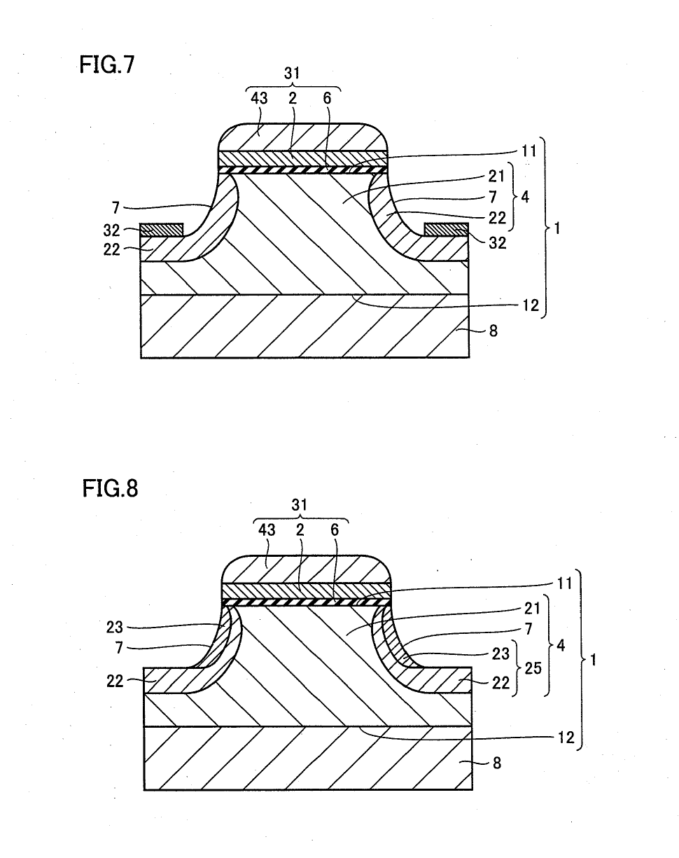

Referring to FIG. 7, a second mask 32 is formed on each of bottom portions of the etched portions of epitaxial layer 1. Second mask 32 is formed to cover a portion of second impurity region 22 (i.e., region provided with the impurity having the second conductivity type by means of the ion implantation). Second mask 32 may be formed to partially cover the vicinity of the lower end of side surface 7 of mesa structure region 4.

Referring to FIG. 8, for example, univalent ions of P (phosphorus) are implanted into side surface 7 of mesa structure region 4 under a condition of 150 keV at a dose amount of 4×10¹⁴cm⁻². In this way, third impurity region 23 having n type conductivity (first conductivity type) is formed. Third impurity region 23 covers second impurity region 22 in side surface 7 of mesa structure region 4. Further, third impurity region 23 is separated from first impurity region 21 by second impurity region 22. Further, the p+ region (fourth impurity region 24: see FIG. 1) may be formed in a portion of second impurity region 22.

Thereafter, an activation annealing step is performed. In the activation annealing step, mesa structure region 4 is annealed at a temperature lower than 1700° C. Preferably, the annealing temperature is 1500° C. or less, more preferably, the annealing temperature is 1400° C. or less.

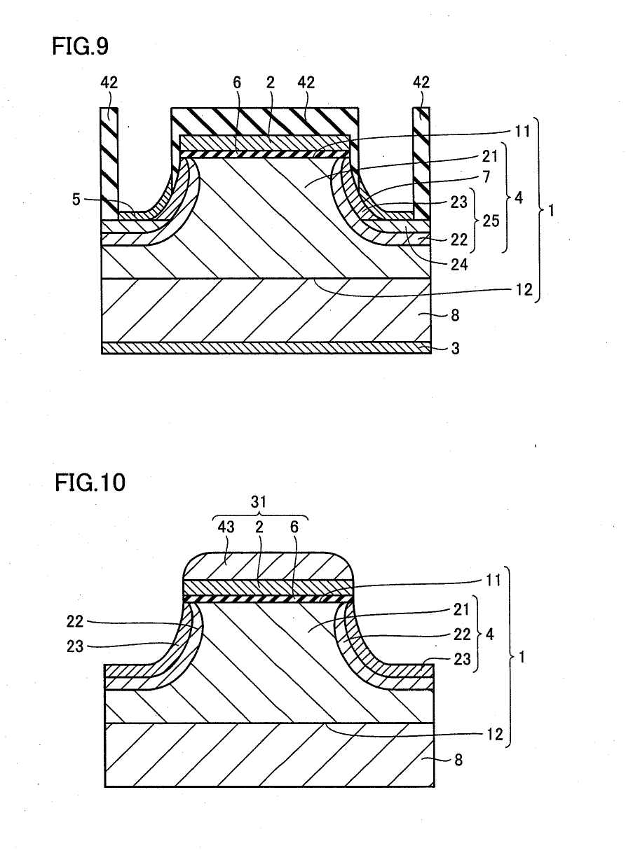

Referring to FIG. 9, a source-drain electrode forming step (step S60: FIG. 14) is performed. Specifically, first, interlayer insulating film 42 is formed to cover gate electrode 2. Thereafter, interlayer insulating film 42 is removed from portions in which the source electrodes are to be formed. Thereafter, source electrodes 5 are formed on side surfaces 7 of mesa structure region 4 and fourth impurity regions 24. Further, each of source electrodes 5 is in contact with third impurity region 23. Source electrode 5 is formed of TiAlSi. Further, drain electrode 3 is formed on second main surface 12 of epitaxial layer 1 with substrate 8 interposed therebetween. The drain electrode is formed of TiAlSi. It should be noted that drain electrode 3 may be formed on second main surface 12 of epitaxial layer 1 with no substrate 8 interposed therebetween.

Referring to FIG. 1 again, a wire forming step (step S70: FIG. 14) is performed. Specifically, wire 41 is formed to make contact with source electrode 5. In this way, silicon carbide semiconductor device 10 according to the present embodiment is completed.

The following describes a first variation of the step of forming impurity implantation region 25.

Referring to FIG. 10, second impurity region 22 and third impurity region 23 may be produced in the following manner. First, ion implantation of an impurity of p type (second conductivity type) is performed into side surface 7 of mesa structure region 4, thereby forming second impurity region 22 in side surface 7. Next, ion implantation of an impurity of n type (first conductivity type) are performed into the region thus provided with the p type impurity by means of the ion implantation, thereby forming third impurity region 23 in side surface 7.

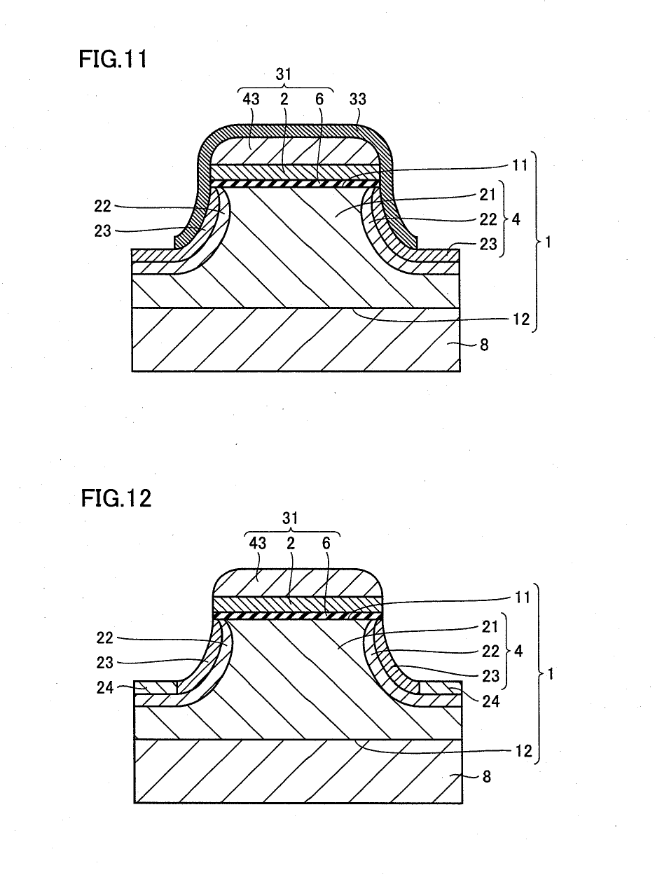

Referring to FIG. 11, a mask (second mask 33) is formed to cover a portion of third impurity region 23 formed in side surface 7 of mesa structure region 4. Second mask 33 may be formed to cover gate insulating film 6, gate electrode 2, and TEOS oxide film 43.

Referring to FIG. 12, ion implantation of an impurity of p type (second conductivity type) are performed into third impurity region 23 using second mask 33, thereby forming the p+region serving as fourth impurity region 24. Thereafter, second mask 33 is removed.

The following describes a second variation of the step of forming impurity implantation region 25.

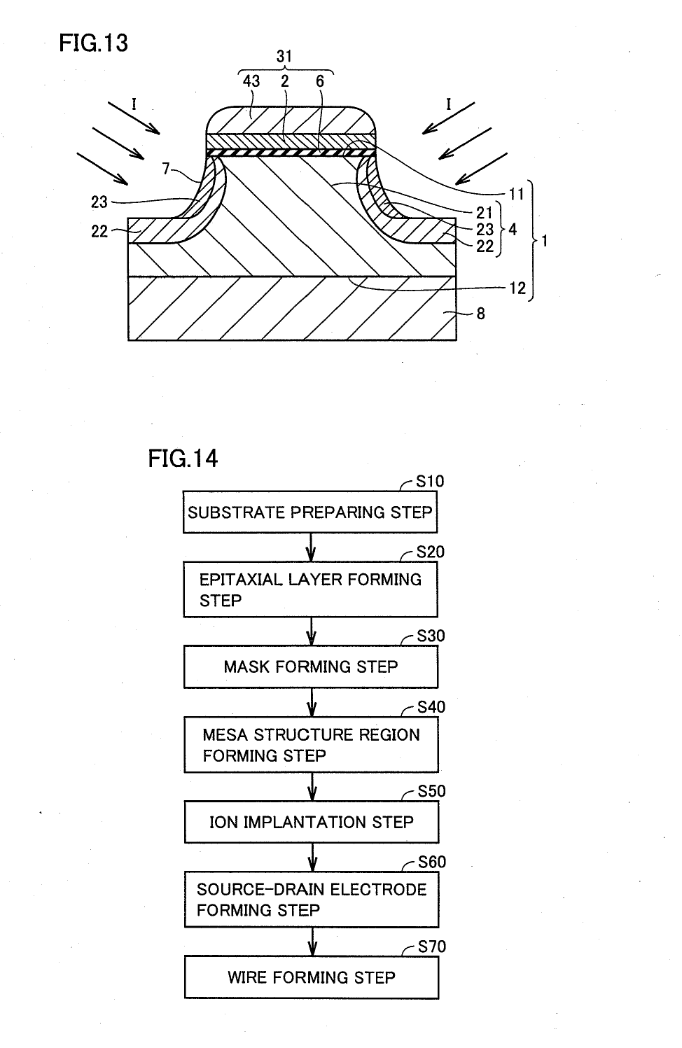

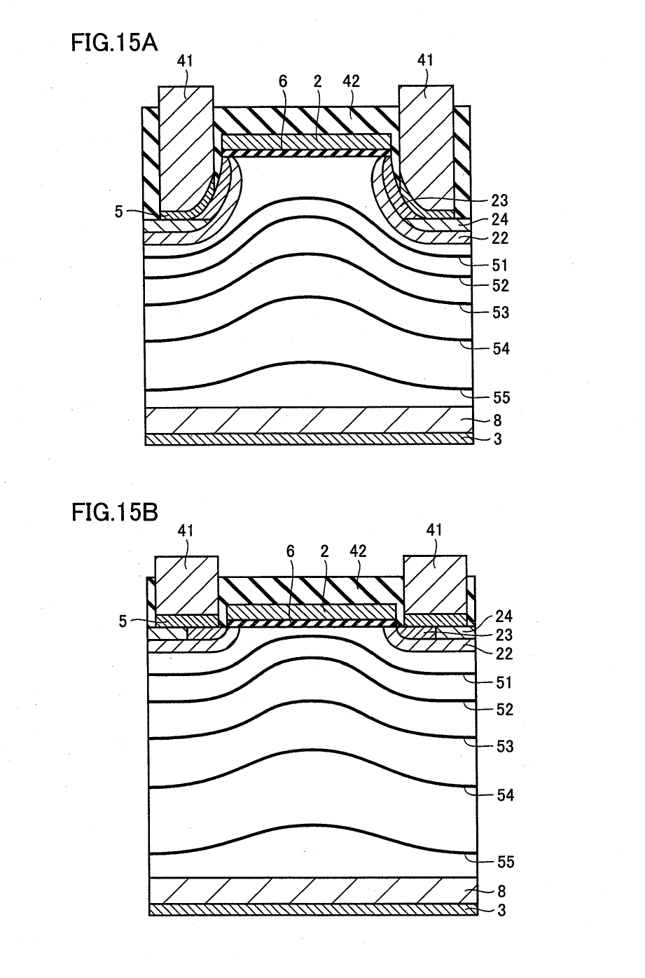

Referring to FIG. 13, second impurity region 22 and third impurity region 23 may be produced in the following manner. First, ion implantation of an impurity of p type (second conductivity type) are performed into side surface 7 of mesa structure region 4, thereby forming second impurity region 22 in side surface 7. In doing so, the ions of the impurity are implanted thereinto in a direction perpendicular to first main surface 11 of epitaxial layer 1. Next, first main surface 11 of epitaxial layer 1 is inclined relative to the direction in which the ion implantation of the impurity is performed. Thereafter, while keeping the inclination relative to the direction in which the ion implantation is performed, ion implantation of an impurity of n type (first conductivity type) are performed into side surface 7 of mesa structure region 4, thereby forming third impurity region 23 in side surface 7. The ion implantation of the impurity is performed in a direction substantially perpendicular to each side surface 7 (direction of arrows I), for example.

By performing the above-described step, second impurity region 22 and third impurity region 23 are foamed without using second masks 32, 33 described above, thus achieving simplified manufacturing process.

The following describes function and effect of the present embodiment.

The silicon carbide semiconductor device according to the present embodiment includes mesa structure region 4 having top surface 11 on which gate insulating film 6 is provided. This leads to reduced electric field strength in gate insulating film 6, thereby improving breakdown voltage of the silicon carbide semiconductor device.

Side surface 7 of mesa structure region 4 is inclined relative to the {0001} plane in the silicon carbide semiconductor device according to the present embodiment. Accordingly, propagation of crystal periodicity is likely to be attained when annealing the impurity regions, thus reducing the annealing temperature.

According to the method for manufacturing the silicon carbide semiconductor device in the present embodiment, first mask 31 includes gate insulating film 6, and gate electrode 2 formed on gate insulating film 6. In this way, each of gate insulating film 6 and gate electrode 2 can be employed as a mask, thus simplifying the manufacturing process.

According to the method for manufacturing the silicon carbide semiconductor device in the present embodiment, the step of forming the impurity implantation region includes the step of performing ion implantation of the impurity having the first conductivity type and the impurity having the second conductivity type in the direction inclined relative to the surface of first mask 31. In this way, the ions are implanted into side surface 7 of mesa structure region 4.

The method for manufacturing the silicon carbide semiconductor device in the present embodiment further includes the step of annealing mesa structure region 4 at a temperature lower than 1700° C. after the step of forming the impurity implantation region. In this way, the annealing temperature can be reduced, thus suppressing surface roughness.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide semiconductor device comprising:
an epitaxial layer that is made of silicon carbide, that has a first main surface and a second main surface opposite to said first main surface, and that includes a mesa structure region having a top surface forming said first main surface and a side surface;
a gate insulating film provided on said top surface of said mesa structure region; and
a gate electrode provided on said gate insulating film,
said mesa structure region including a first impurity region having first conductivity type and an impurity implantation region provided in said side surface, said impurity implantation region including a second impurity region and a third impurity region, said second impurity region having second conductivity type different from said first conductivity type, said second impurity region being in contact with said gate insulating film, said third impurity region covering said second impurity region in said side surface, said third impurity region being separated from said first impurity region by said second impurity region, said third impurity region having said first conductivity type, the silicon carbide semiconductor device further comprising:
a drain electrode provided on said second main surface; and
a source electrode in contact with said third impurity region.

2. The silicon carbide semiconductor device according to claim 1, wherein said third impurity region is in contact with said gate insulating film.

3. The silicon carbide semiconductor device according to claim 1, wherein said side surface is inclined relative to a {0001} plane.

4. The silicon carbide semiconductor device according to claim 1, wherein said side surface and a bottom surface of said mesa structure region form an angle of not less than 45° and not more than 100°.

5. A method for manufacturing a silicon carbide semiconductor device that includes a mesa structure region having a top surface and a side surface and that is provided with a gate electrode on said top surface with a gate insulating film interposed therebetween, the method comprising the steps of:
forming an epitaxial layer that is made of silicon carbide, that has a first main surface and a second main surface opposite to said first main surface, and that has a first impurity region having first conductivity type;
forming a first mask on said first main surface of said epitaxial layer;
forming said mesa structure region in said first main surface of said epitaxial layer by etching said first main surface of said epitaxial layer using said first mask;
forming an impurity implantation region in said side surface of said mesa structure region, the step of forming said impurity implantation region including the step of forming a second impurity region having second conductivity type different from said first conductivity type and a third impurity region having said first conductivity type, said second impurity region being formed in contact with said gate insulating film, said third impurity region being formed to cover said second impurity region in said side surface and to be separated from said first impurity region by said second impurity region;
forming a drain electrode on said second main surface of said epitaxial layer; and
forming a source electrode in contact with said third impurity region.

6. The method for manufacturing the silicon carbide semiconductor device according to claim 5, wherein said first mask includes said gate insulating film and said gate electrode formed on said gate insulating film.

7. The method for manufacturing the silicon carbide semiconductor device according to claim 5, wherein the step of forming said impurity implantation region includes the step of performing ion implantation of an impurity having said first conductivity type and an impurity having said second conductivity type in a direction inclined relative to said first main surface.

8. The method for manufacturing the silicon carbide semiconductor device according to claim 5, further comprising the step of annealing said mesa structure region at a temperature lower than 1700° C. after the step of forming said impurity implantation region.

9. The method for manufacturing the silicon carbide semiconductor device according to claim 5, wherein
the step of forming said impurity implantation region including the steps of:
performing ion implantation of an impurity having said second conductivity type into said side surface;
forming a second mask to cover a portion of a region provided with the impurity having said second conductivity type by means of the ion implantation; and
performing ion implantation of an impurity having said first conductivity type into the region provided with the impurity having said second conductivity type by means of the ion implantation, using said second mask.

10. The method for manufacturing the silicon carbide semiconductor device according to claim 5, wherein
the step of forming said impurity implantation region includes the steps of:
performing ion implantation of an impurity having said second conductivity type into said side surface;
performing ion implantation of an impurity having said first conductivity type into a region provided with the impurity having said second conductivity type by means of the ion implantation;
forming a second mask to cover a portion of a region provided with the impurity having said first conductivity type by means of the ion implantation; and
performing ion implantation of an impurity having said second conductivity type into the region provided with the impurity having said first conductivity type by means of the ion implantation, using said second mask.

11. The method for manufacturing the silicon carbide semiconductor device according to claim 5, wherein
the step of forming said impurity implantation region including the steps of:
performing ion implantation of an impurity having said second conductivity type into said side surface;
inclining said first main surface of said epitaxial layer relative to a direction in which the ion implantation is performed; and
while keeping the inclination relative to said direction in which the ion implantation is performed, performing ion implantation of an impurity having said first conductivity type into a region provided with the impurity having said second conductivity type by means of the ion implantation.
